(19) United States
(12) Patent Application Publication
(10) Pub. No.: US 2012/0112252 A1
(43) Pub. Date: May 10, 2012

(54) SEMICONDUCTOR STRUCTURE AND METHOD FOR MANUFACTURING THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignee: Institute of Microelectronics, Chinese Academy of Sciences, Bijing (CN)

(21) Appl. No.: 13/380,380

(22) PCT Filed: Feb. 27, 2011
(86) PCT No.: PCT/CN11/71349

§ 371 Date: Dec. 22, 2011

(30) Foreign Application Priority Data
Oct. 29, 2010 (CN) 201010526916.2

(51) Int. Cl. H01L 29/772; H01L 21/28

(52) U.S. Cl. 257/288; 438/586; 257/E21.19; 257/E29.242

(57) ABSTRACT

The present invention provides a method for manufacturing a semiconductor structure, which lies in covering a first dielectric layer with a second dielectric layer, forming a first contact hole with a small inner diameter within the second dielectric layer first, then etching the first dielectric layer to form a second contact hole with a much great inner diameter, and finally filling a conductive material into the first contact hole and the second contact hole to form contact plugs. Accordingly, the present invention further provides a semiconductor structure favorable for reducing contact resistance.

### FIELD OF THE INVENTION

The present invention relates to the technical field of semiconductor manufacturing, and specifically, to a semiconductor structure and a method for manufacturing the same.

### BACKGROUND OF THE INVENTION

With the development of the semiconductor industry, integrated circuits with better performance and more powerful functions require greater element density. Thus, sizes of components needs to be further scaled down, and the contact area between source/a drain regions and a metal electrode may be reduced accordingly. However, the reduction of the contact area may significantly increase contact resistance.

As shown in FIG. 9, US patent application No. US2010/010904A1 in the prior art disclosed a method for reducing contact resistance at source/drain regions, which comprises following steps:

etching a first dielectric layer 110 above source/drain regions 116 to form a reverse tapered contact hole 130 so as to expose the source/drain regions 116;

preamorphizing a portion of the source/drain regions 116 through the contact hole by means of ion implantation to form a local amorphous silicon region 114;

implantating doped ions into the source/drain regions with Boron;

forming a metal layer on the amorphous region at bottom of the contact hole;

annealing to form a metal silicide layer 124 by silicidation of the portion of the metal in contact with the amorphous silicon, whereas the amorphous silicon which does not undergo reaction still exists under the metal silicide layer; and

removing the metal that has not been silicified and filling to form a metal electrode.

The existence of the transition area of the metal silicide and the amorphous silicon layer between the source/drain regions and the metal electrode may effectively reduce resistivity between the source/drain regions and the metal electrode, and further reduce the contact resistance.

However, in aforesaid technique of the prior art, the area at bottom of the contact hole decreases with the scaling of devices, which may lead to limited reduction of the contact resistance. In order to further improve performance of semiconductor devices, the area at bottom of the contact hole has to be increased so as to form a much larger contact area, which thereby further reduces the contact resistance.

### SUMMARY OF THE INVENTION

In view of abovementioned shortcomings, the present invention aims to provide a method for manufacturing a semiconductor structure, which is capable of increasing the contact area between a contact plug and a source/drain regions when manufacturing a semiconductor structure, so as to reduce contact resistance.

In order to solve aforesaid technical problems, the present invention provides a method for manufacturing a semiconductor structure, which comprises:

a) providing a substrate having source/drain regions, forming a gate stack on the substrate, and forming a first dielectric layer on the substrate to cover the source/drain regions and the gate stack;
b) forming a second dielectric layer on the first dielectric layer or on the first dielectric layer and the gate stack, wherein the material of the second dielectric layer is different from the material of the first dielectric layer;
c) etching the second dielectric layer to form a first contact hole that reaches the first dielectric layer;
d) etching the first dielectric layer through the first contact hole to form a second contact hole that reaches the source/drain regions, wherein the cross-sectional area of the second contact hole is larger than the cross-sectional area of the first contact hole; and
e) filling the first contact hole and the second contact hole with a conductive material, and planarizing the conductive material to expose the second dielectric layer so as to form a contact plug, such that the cross-sectional area of the contact plug embedded into the second dielectric layer is smaller than the cross-sectional area of the contact plug embedded into the first dielectric layer.

Accordingly, the present invention further provides a semiconductor structure, which comprises a substrate, a gate stack, a first dielectric layer, a second dielectric layer and a contact plug, wherein:

the source/drain regions are embedded into the substrate;

the gate stack is formed on the substrate;

the first dielectric layer covers the source/drain regions, and the second dielectric layer covers the first dielectric layer or covers the first dielectric layer and the gate stack;

the contact plug is embedded into the first dielectric layer and the second dielectric layer, wherein the cross-sectional area of the contact plug embedded into the second dielectric layer is smaller than the cross-sectional area of the contact plug embedded into the first dielectric layer.

In use of the semiconductor structure and the method for manufacturing the same provided by the present invention, the cross-sectional area of the second contact hole is made to be larger than the cross-sectional area of the first contact hole, which thus is able to form a quite big contact plug that is able to reduce the contact resistance between the contact plug and source/drain regions; besides, at formation of the contact plug, a second dielectric layer is covered on the gate, which is favorable for diminishing probability of short circuits occurring between a gate stack and source/drain arising from inaccurate positioning of a contact hole.

### BRIEF DESCRIPTION OF THE DRAWINGS

Other characteristics, objectives and advantages of the present invention will be evident according to perusal of the following detailed description of exemplary embodiment(s) in conjunction with accompanying drawings.

FIG. 1 illustrates a flowchart of a method for manufacturing a semiconductor structure according to an embodiment the present invention;

FIG. 2 to FIG. 8 are cross-sectional views of intermediate structures at respective stages in manufacturing a semiconductor structure according to the method shown in FIG. 1; and

FIG. 9 illustrates a semiconductor structure for reducing contact resistance at the source/drain regions in the US patent application US2010/010904A1.

The same or similar reference numbers in the accompanying drawings denote the same or similar elements.

### DETAILED DESCRIPTION OF THE INVENTION

Other characteristics, objectives and advantages of the present invention will be more evident according to the following detailed description of exemplary embodiments and the accompanying drawings.

Described below in detail are the embodiments of the present invention, examples of which are also illustrated in the drawings. The same or similar reference numbers in the accompanying drawings denote the same or similar elements, or elements having the same or similar functions, throughout the drawings. The embodiments described below with reference to the drawings are merely illustrative, and are provided for explaining the present invention only, and thus should not be interpreted as limiting the present invention.

Various embodiments or examples are provided hereinafter to implement different structures of the present invention. To simplify the disclosure of the present invention, description of the components and arrangements of specific examples is given below. Of course, they are only illustrative and not limiting the present invention. Moreover, in the present invention, reference numbers and/or letters may be repeated in different embodiments. Such repetition is for the purposes of simplification and clearness, and does not denote the relationship between respective embodiments and/or arrangements being discussed. Furthermore, the present invention provides various examples for specific process and materials. However, it is obvious for a person of ordinary skill in the art that other processes and/or materials may alternatively be utilized. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other.

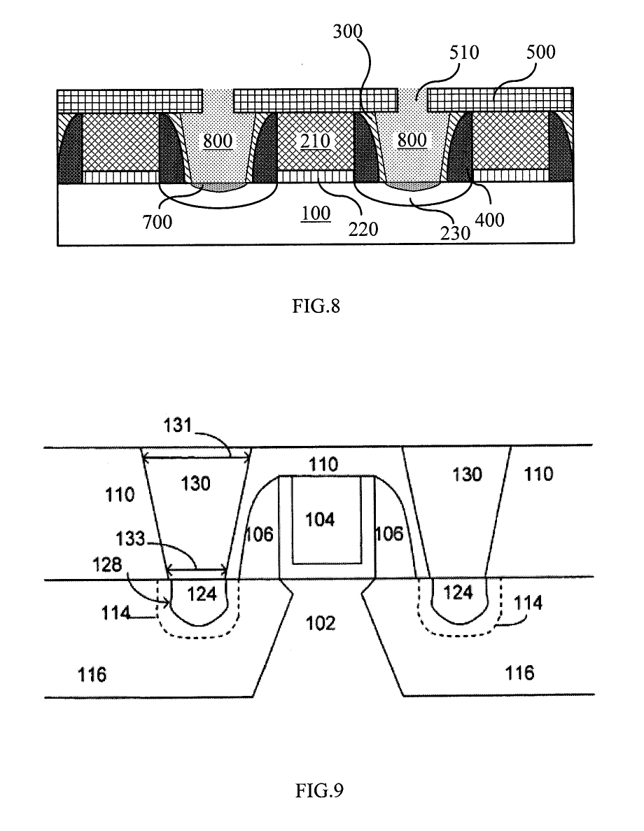

First, a semiconductor structure provided by the present invention is generally described herein. As shown in FIG. 7 and FIG. 8, the semiconductor structure comprises a substrate 100, a gate stack, sidewall spacers 400 (the example of a semiconductor structure having sidewall spacers 400 is illustrated herein, whereas the sidewall spacers may not be formed in a semiconductor structure in other embodiments), a first dielectric layer 300, a second dielectric layer 500 and a contact plug 800, wherein:

the source/drain regions 230 are formed in the substrate 100;

the gate stack is formed on the substrate 100, and the sidewall spacers 400 are formed on sidewalls of the gate stack;

the first dielectric layer 300 covers the source/drain regions 230, and the second dielectric layer 500 covers the first dielectric layer 300, or covers both the first dielectric layer 300 and the gate stack; and

the contact plug 800 is embedded into the first dielectric layer 300 and the second dielectric layer 500, wherein the cross-sectional area of the contact plug 800 embedded into the second dielectric layer 500 is smaller than that of the contact plug 800 embedded into the first dielectric layer 300. Specifically, the gate stack comprises a gate metal 210 and a gate dielectric layer 220. The material of the contact plug 800 is W, Al, TiAl alloy or their combinations.

Optionally, a contact layer 700 may be formed between the contact plug 800 and the source/drain regions 230. The contact layer 700 is located adjacent to the source/drain regions 230. Particularly, the contact layer 700 may be only sandwiched between the contact plug 800 and the source/drain regions 230. The substrate 100 may be a silicon substrate. The contact layer 700 may be a metal silicide such as SiNi, SiTi, SiCo or SiCu. Additionally, a liner is formed on the sidewalls of the first contact hole 510 and/or on the sidewalls of the second contact hole 310, and a liner is formed between the contact plug 800 and the source/drain regions 230 (The liner is not shown in the drawings, and the material of which may be Ti, TiN, Ta, TaN, Ru or their combinations. The contact plug 800 is electrically connected with the source/drain regions 230 by the liner).

In other specific embodiments of the present invention, the source/drain regions 230 are raised source/drain regions (i.e. the top of the source and the drain regions 230 are epitaxially grown to be higher than the bottom of the gate stack), then the second contact hole 310 extends to such a position inside the source/drain regions 230 that is at the same level as the bottom of the gate stack (herein, the term “at the same level” or “on the same plane” means that the height difference is within the processing tolerance). Of course, in other embodiments of the present invention, the source/drain regions 230 may not be raised source/drain regions, and the bottom of the second contact hole 310 may be at the same level as the bottom of the gate stack. A amorphous layer may further be conformally formed between the contact layer 700 and the source/drain regions 230. The term “conformally” means that the amorphous layer has a uniform thickness and the shape thereof are identical with the shapes of the bottom and sidewalls of the second contact hole 230.

Optionally, in some specific embodiments of the present invention, the material of the first dielectric layer 300 may be FSG, BSG, PSG, USG, SiON, a low-k material or their combinations (e.g., the first dielectric layer 300 may be a multi-layer structure, and the neighboring two layers may be made of different materials). The material of the second dielectric layer 500 may be selected from the same group as that of the first dielectric layer 300, which thus is not described here in order not to obscure the disclosure. Preferably, the material of the second dielectric layer 500 is SiN. In other specific embodiments, the material of the first dielectric layer may be the same as that of the second dielectric layer.

Hereinafter, a method for manufacturing the semiconductor structure is described.

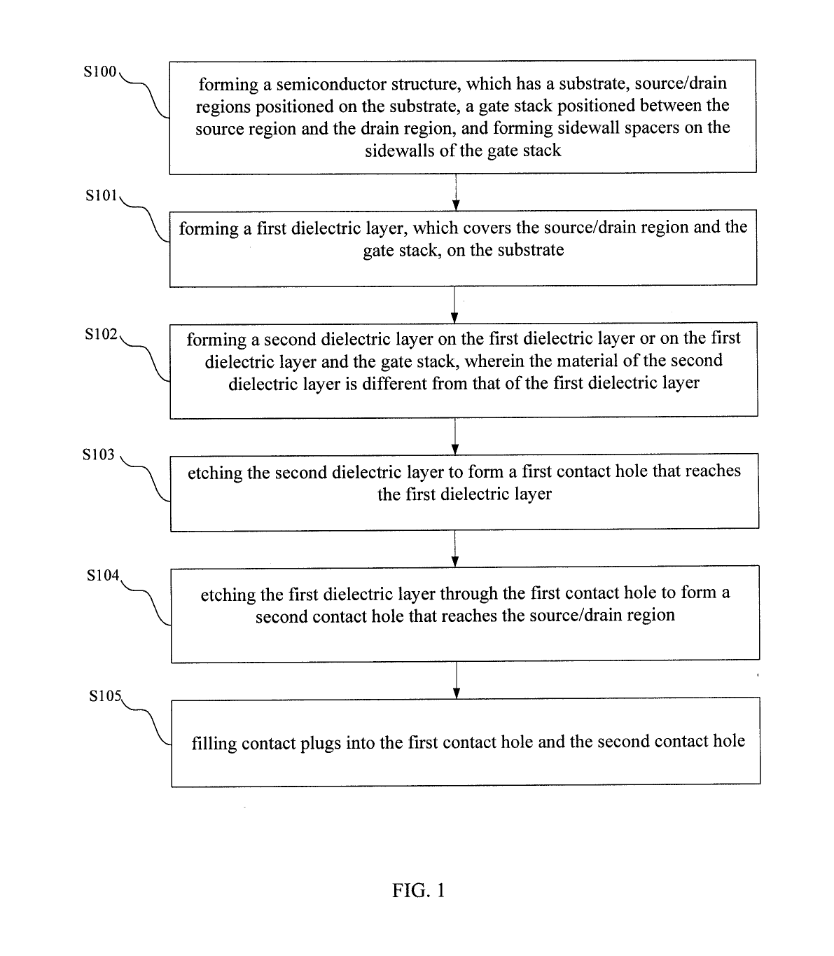

With reference to FIG. 1, the method comprises:

at step S100, providing a substrate 100 that has source/drain regions 230; forming a gate stack on the substrate, and forming sidewall spacers on the sidewalls of the gate stack, wherein the gate stack comprises a gate dielectric layer and a metal gate layer;

at step S101, forming a first dielectric layer, which covers the source/drain regions and the gate stack, on the substrate;

at step S102, forming a second dielectric layer on the first dielectric layer or on both the first dielectric layer and the gate stack, wherein the material of the second dielectric layer is different from the material of the first dielectric layer;

at step S103, etching the second dielectric layer to form a first contact hole that reaches the first dielectric layer;

at step S104, etching the first dielectric layer 300 through the first contact hole 510 to form a second contact hole 310 that reaches the source/drain regions 230, wherein the cross-sectional area of the second contact hole 310 is larger than the cross-sectional area of the first contact hole 510; and

at step 105, after filling the first contact hole 510 and the second contact hole 310 with a conductive material, planarizing the conductive material to expose the second dielectric layer 500 so as to form a contact plug 800, such that the cross-sectional area of the contact plug 800 embedded into the second dielectric layer 500 is smaller than the cross-sectional area of the contact plug 800 embedded into the first dielectric layer 300.

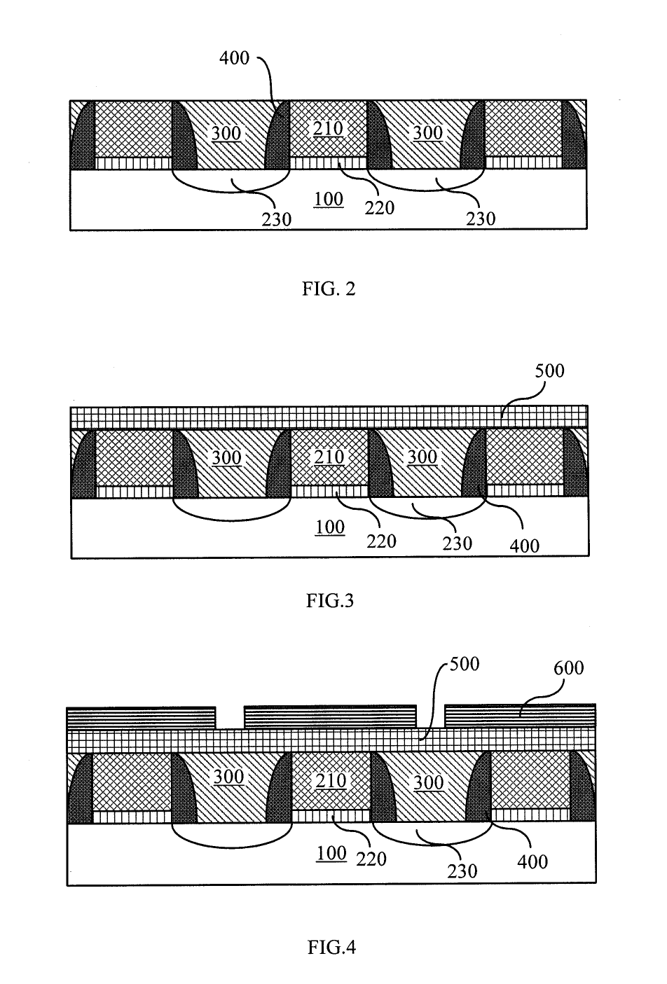

The steps S100 and the step S105 are described herein in conjunction with FIG. 2 to FIG. 8. However, it is should be noted that the drawings of the embodiments of the present invention are merely illustrative and thus are not drawn to scale. It is noticeable that a semiconductor device is formed after implementation of step S100. As shown in FIG. 2, the semiconductor device comprises: a substrate 100, source/drain regions 230 formed within the substrate 100, a gate stack formed on the substrate 100, and sidewall spacers 400 formed on sidewalls of the gate region.

In the present embodiment, the substrate 100 includes a silicon substrate (e.g. silicon wafer). According to the well known designing requirements in the prior art (e. g. a P-type substrate or an N-type substrate), the substrate 100 may be of various doping configurations. Other examples of the substrate 100 may also include other basic semiconductors, for example, germanium. Alternatively, the substrate 100 may include compound semiconductors, for example, Si:C, GaAs, InAs or InP. Typically, the substrate 100 may have, but not limited to, a thickness of about several hundred micrometers, which, for example, may be in the range of 400 um-800 um.

The source/drain regions 230 may be formed by way of implanting P-type or N-type dopants or impurities into the substrate 100. For example, for a PMOS, the source/drain regions 230 may be P-type doped SiGe. For an NMOS, the source/drain regions 230 may be N-type doped Si. The source/drain regions 230 may be formed by way of lithography, ion implantation, diffusion and/or any other method as appropriate. In the present embodiment, the source/drain regions 230 are located within the substrate 100, while in other embodiments, the source/drain regions may be raised source/drain regions formed by means of selective epitaxial growth so that the top of the epitaxial portion is higher than the bottom of the gate stack.

Optionally, in step S100, a gate stack is formed. In the Gate-First Process, the gate stack comprises a gate and a gate dielectric layer 220 that carries the gate. In the Gate-Last Process, the gate stack comprises a dummy gate and a gate dielectric layer 220 that carries the dummy gate. Particularly, sidewall spacers 400 are formed on the sidewalls of the gate stack for separating the gates. The sidewall spacers 400 may be made of a material such as Si₃N₄, SiO₂, SiON, SiC and/or other materials as appropriate. The sidewall spacers 400 may be a multi-layer structure. The sidewall spacers 400 may be formed by way of depositing and etching, and the thickness thereof is in the range of about 10 nm-100 nm.

With reference to FIG. 1 and FIG. 2, step S101 is implemented to form a first dielectric layer 300, which covers the source/drain regions 230, the gate stacks and the sidewall spacers 400, on the substrate 100 (as shown in the drawings, the space between the gate stacks also is filled by the first dielectric layer 300). The first dielectric layer 300 my be formed on the substrate 100 by means of Chemical Vapor Deposition (CVD), High density Plasma CVD or other methods as appropriate. The materials for the first dielectric layer 300 may include FSG, BPSG, PSG, USG, SiON, a low-k material or their combinations (e.g., the first dielectric layer 300 may be a multi-layer structure, in which neighboring layers may be made of different materials). The material for a second dielectric layer 500 is selected from the same group as that of the first dielectric layer 300, and thus it is not described herein in order not to obscure the disclosure. The thickness of the first dielectric layer 300 is in the range of about 40 nm-150 nm.

In the present embodiment, the first dielectric layer 300 and the gate stack are planarized by means of Chemical-Mechanical Polish (CMP), as shown in FIG. 2, such that the upper surface of the gate stack and the upper surface of the first dielectric layer 300 are substantially on the same plane, and the top of both the gate stack and the sidewall spacers 400 are exposed. The Replacement Gate process may be implemented in the case the gate stack comprises a dummy gate. Specifically, the dummy gate is firstly removed. Then a metal gate layer is deposited into the groove formed from removal of the dummy gate. And then the metal gate layer is planarized, such that the top of the metal gate layer is flushed with the first dielectric layer 300. The gate dielectric layer 220 is positioned on the substrate 100, and it may be a thermal oxide layer, including SiO₂, SiON, and further may be a deposited high-k dielectric, for example, any one of HfO₂, HfSiO, HfSiON, HfTaO, HfTiO, HfZrO, Al₂O₃, La₂O₃, ZrO₂ and LaAlO, or their combinations, and the thickness of the gate dielectric layer 220 is about 1 nm-3 nm. A work function metal layer (i.e. gate metal 210) is formed on the gate dielectric layer 220 by way of depositing, for example, one of TaC, TiN, TaTbN, TaErN, TaYbN, TaSiN, HfSiN, MoSiN, RuTax and NiTaₓ, or their combinations, whose thickness is about 10 nm-20 nm. In the present embodiments, the upper surface of the first dielectric layer 300 is at the same level as the upper surface of the gate metal 210. In other embodiments, the upper surface of the first dielectric layer 300 may be higher than the upper surface of the gate metal 210. In an embodiment where the upper surface of the first dielectric layer 300 is higher than the upper surface of the gate metal 210, the process has to be controlled when forming a second contact hole that is embedded into the first dielectric layer 300, such that the first dielectric layer 300 that covers the gate metal 210 shall not be removed.

With reference to FIG. 1 and FIG. 3, step S102 is implemented to form a second dielectric layer 500. The second dielectric layer 500 may be formed on the first dielectric layer 300 or on both the first dielectric layer 300 and the gate stack by means of Chemical Vapor Deposition (CVD), Atom Layer Deposition (ALD), Plasma Enhanced Atom Layer Deposition (PEALD), Pulse Laser Deposition (PLD) or other methods as appropriate. Preferably, the material of the second dielectric layer 500 may be SiN. However, it is should be noted that different materials are respectively selected for the second dielectric layer 500 and the first dielectric layer 300 so as to perform selective etching, which may diminish damage to the region covered by the second dielectric layer 500 when the first dielectric layer 300 is etched.

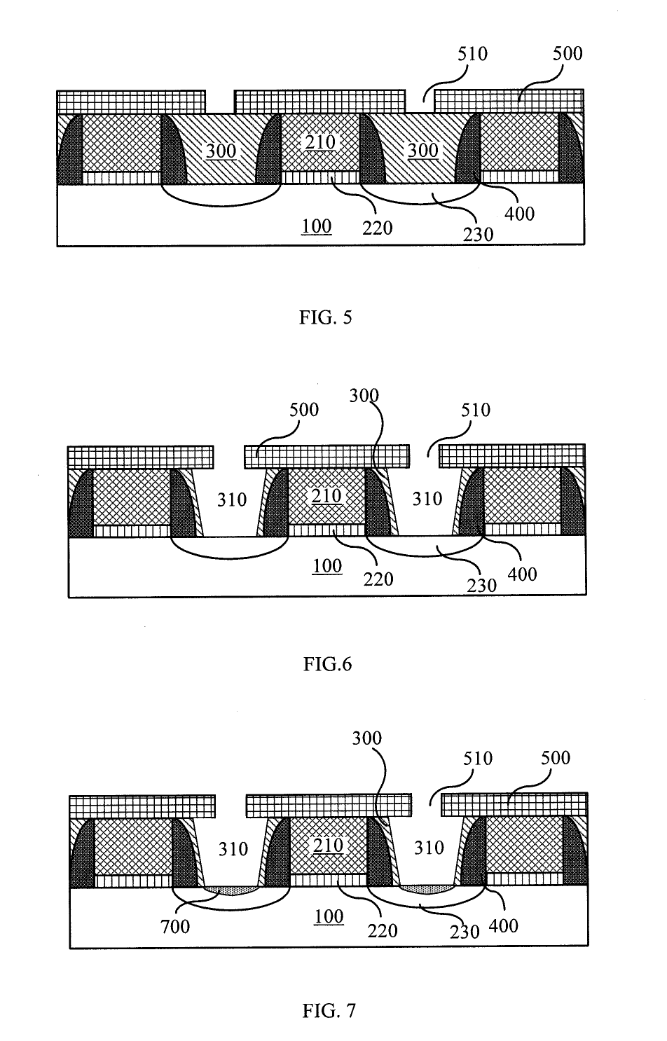

Next, step S103 is implemented to etch the second dielectric layer to form a first contact hole. With reference to FIG. 1, FIG. 4 and FIG. 5, a photoresist layer 600 is covered on the second dielectric layer 500 first, then the photoresist layer 600 is exposed and patterned to form an aperture whose position is above the source/drain region 230 and corresponds to the position where the first contact hole 510. As shown in FIG. 5, selective etching is performed to the second dielectric layer 500 by means of lithography and is stopped on the first dielectric layer 300, so as to form a first contact hole 510. Preferably, anisotropic etching is applied in the present embodiment. In the present embodiment, the first contact hole 510 may be formed by various means including, but not limited to, dry etching or wet etching. As shown in FIG. 5, after the first contact hole 510 is formed, the first dielectric layer 300 under the second dielectric layer 500 is exposed, and therefore the next step S104 may be performed subsequently.

Step S104 is implemented to etch the first dielectric layer to form a second contact hole. With reference to FIG. 1 and FIG. 6, the first dielectric layer 300 may be etched selectively through the first contact hole 510 to form a second contact hole 310. Specifically, the second contact hole 310 may be etched by way of dry etching, wet etching or an appropriate etching method according to the manufacturing requirements. After the second contact hole 310 is formed, the source/drain regions 230 within the substrate 100 are exposed, which is favorable for implementing next step S105. In the present embodiment, it is also applicable to perform anisotropic etching to etch a portion of the first dielectric layer 300 so as to form an aperture whose diameter is substantially identical with that of the first contact hole 510. Then isotropic etching process is performed to expand the aperture, so as to form a second contact hole 310 whose cross-sectional area is larger than that of the first contact hole 510. In other embodiments, an appropriate etching method may be selected to form a second contact hole 310. For example, an isotropic etching process is performed directly (e.g. dry etching or wet etching) to form a second contact hole 310, such that the inner diameter or the cross-sectional area of the second contact hole 310 is larger than the inner diameter or the cross-sectional area of the first dielectric layer 510. The formed second contact hole 310 may not have a uniform inner diameter along the length direction. Since the upper portion of the second contact hole 310 is etched for a longer time than the lower portion of the second contact hole 310, the lower inner diameter or the cross-sectional area of the second contact hole 310 in contact with the source/drain regions 230 may be smaller than the upper inner diameter or the cross-sectional area thereof. However, the lower inner diameter or the cross-sectional area of the second contact hole 310 in contact with the source/drain regions 230 should be larger than the inner diameter or the cross-sectional area of the first contact hole 510. Since the gate stack is protected by the second dielectric layer 500 and the sidewall spacers 400, even if the second contact hole 310 is over-etched, shorts between the gate and the source/drain may not occur. It is possible to effectively reduce the contact resistance by the increase of the contact area between the bottom of the second contact hole 310 and the source/drain regions 230.

If the source/drain regions 230 are raised source/drain structures formed by selective epitaxial growth, and the top of the epitaxial portion is higher than the bottom of the gate stack, then the second contact hole 310 may be formed at such a position within the source/drain regions 230 that is at the same level as the bottom of the gate stack. Therefore, when a contact plug 800 is formed within the second contact hole 310, the contact plug 800 may be in contact with the source/drain regions 230 by a portion of the sidewalls and the bottom of the second contact hole 310, so as to further increase the contact area and to reduce the contact resistance accordingly.

Optionally, after implementation of step S104, a contact layer 700 (for example, for a silicon substrate, the contact layer 700 is a metal silicide) is formed on the exposed source/drain regions 230. With reference to FIG. 7, the part below the second contact hole 310 is the exposed source/drain region 230 and a metal is deposited on the source/drain region 230, which is then annealed to form a contact layer 700. Specifically, pre-amorphous process is performed to the exposed source/drain region through the second contact hole 310 by means of ion implantation, amorphous compound depositing or in-situ doping growth, so as to form a partially amorphous region. Since the ion implantation is prone to cause end defect, thus it is preferred to form an amorphous compound by way of depositing an amorphous compound or using in-situ doping growth method in the present invention. Then, a metal layer is formed on the amorphous region by way of metal sputtering or Chemical Vapor Deposition; preferably, the metal may be Ni. The metal also may be any other metal as appropriate, for example, Ti or Co, etc. Then the semiconductor structure is annealed; in other embodiments, other annealing processes, for example, rapid thermal annealing and spike annealing, may be used. According to the embodiments of the present invention, a device is usually annealed by means of instant annealing process; for example, laser annealing is performed under the temperature of 1000° C. for a period of a microsecond, such that the deposited metal reacts with the amorphous compound formed within the source/the drain region 230 to form a contact layer 700; in view of the deposited different metal layers, the contact layer 700 may be SiNi, SiTi, SiCo or SiCu or other metal silicide (a silicon substrate is taken as an example). Finally, the deposited metal that remains after the reaction may be removed by using a chemical etching method. The amorphous compound may be any one of amorphous silicon, amorphous SiGe or amorphous Si:C. The advantage of forming the metal silicide 700 is its capability of reducing resistivity between the contact plug 800 and the source/the drain region 230, so as to further reduce the contact resistance. When the un-reacted metal is removed, the second dielectric layer 500 formed on the gate diminishes damage to the gate.

In conjunction with FIG. 1 and FIG. 8, step S105 is implemented to fill a conductive material (e.g. metal) into the first contact hole 510 and the second hole 310. As shown in FIG. 8, contact plugs 800 are formed within the first contact hole 510 and the second contact hole 310 by means of deposition; the contact plugs 800 fill the first contact hole 510 and the second contact hole 310; the contact plugs 800 may be electrically connected with the exposed source/drain regions 230 within the substrate 100 via the contact layers 700 (e.g.

a metal silicide) formed on the exposed source/drain regions 230 within the substrate 100, and go through the second dielectric layer 500 and the exposed upper part through the first contact hole 510. Preferably, the material of the contact plugs 800 is W. Of course, according to needs of manufacturing a semiconductor structure, the materials for the contact plugs 800 may be any one or a combination of W, Al, TiAl alloy or their combinations. Before the contact plug 800 is filled, a liner (not shown in the drawings) may be formed on the sidewalls of the first contact hole 510, the sidewalls and the bottom of the second contact hole 310; the liner may be formed by deposition processes such as ALD, CVD, PVD, and the material for the liner may be Ti, TiN, Ta, TaN, Ru or their combinations.

Optionally, after step S106 is implemented, in the present embodiment, Chemical-Mechanical Polish (CMP) is performed to the second dielectric layer 500 and the contact plug 800, as shown in FIG. 8, such that the upper surface of the second dielectric layer 500 and the contact plug 800 are on the same plane, and the contact plug 800 is exposed.

Optionally, according to the needs for manufacturing a semiconductor structure, it is applicable to form a contact plug by depositing contact metal into a gate contact hole, after the gate contact hole is formed on the second dielectric layer 500 that corresponds to the position next to the gate stack by means of lithography process. Then, a metal interconnect layer may be formed on the semiconductor structure of the present embodiment; the arrangement of the metal interconnect layer is applied to selectively connect with the contact plug at the gate stack or to the contact plug 800 at the source/drain region 230, thus it is able to form different internal circuits of the semiconductor structures that meet different manufacturing needs.

The method for manufacturing a semiconductor structure provided by the present invention is implemented, that is, a first dielectric layer 300 is covered by a second dielectric layer 500; at first, a first contact hole 510 with a small inner diameter is formed within the second dielectric layer 500, then the first dielectric layer 300 is etched to form a second contact hole 310 with a much large inner diameter; finally, contact plugs 800 are filled into the first contact hole 510 and the second contact hole 310. Since the gate stacks are well protected by the second dielectric layer 500 and the sidewall spacers 400, thus it is able to restrain occurrence of a short circuit between the gate and the source/drain arising from over-etching when the first dielectric layer is etched according to the prior art. Since the area exposed at the head of the contact plug 800 that connects with the source/drain is much small and is far away from the gate, thus it is easy to avoid a short circuit between the gate and source/drain occurring at formation of a contact hole of the gate, and also is favorable for implementation of the subsequent processes. Whereby, the area of the lower portion of the metal in contact with the substrate 100 is quite large, thus it reduces the resistance between the contact plug and source/drain regions, thereby improving performance of the semiconductor structure.

Although the exemplary embodiments and their advantages have been described in detail, it should be understood than various alternations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising:
a) providing a substrate having source/drain regions, forming a gate stack on the substrate, and forming a first dielectric layer on the substrate to cover the source/drain regions and the gate stack;
b) forming a second dielectric layer on the first dielectric layer or on the first dielectric layer and the gate stack, wherein the material of the second dielectric layer is different from the material of the first dielectric layer;
c) etching the second dielectric layer to form a first contact hole that reaches the first dielectric layer;
d) etching the first dielectric layer through the first contact hole to form a second contact hole that reaches the source/drain regions, wherein the cross-sectional area of the second contact hole is larger than the cross-sectional area of the first contact hole; and
e) filling the first contact hole and the second contact hole with a conductive material, and planarizing the conductive material to expose the second dielectric layer so as to form a contact plug, such that the cross-sectional area of the contact plug embedded into the second dielectric layer is smaller than the cross-sectional area of the contact plug embedded into the first dielectric layer.

2. The method according to claim 1, wherein at step d), a second contact hole is formed by implementing anisotropic etching process through the first contact hole, and then the second contact hole is extended by means of isotropic etching process.

3. The method according to claim 1, wherein the second contact hole stops at the upper surface of the source/drain region or reaches into the source/drain region.

4. The method according to claim 3, wherein when the second contact hole extends into the source/drain region, the lower end of the second contact hole is at the same level as the bottom of the gate stack.

5. The method according to claim 1, wherein step d1) is further implemented between step d) and step e), and step d1) comprises:
forming a metal layer on the exposed source/drain regions;
performing annealing such that the metal layer reacts with the source/drain regions that carry the metal layer to form a contact layer; and
removing the un-reacted metal layer to form a contact layer.

6. The method according to claim 5, wherein the step of forming a metal layer comprises:
performing a pre-amorphous process to the exposed source/drain regions by means of ion implantation, amorphous compound deposition or in-situ doping growth, so as to form a local amorphous region; and
forming the metal layer on the local amorphous region.

7. The method according to claim 5, wherein the material for the metal layer is one of Ni, Ti, Co and Cu, or their combinations.

8. The method according to claim 1, wherein prior to filling the first contact hole OA and the second contact hole to form the contact plug at step e), step e) further comprises:
forming a liner on sidewalls of the first contact hole and on sidewalls and bottom of the second contact hole.

9. The method according to claim 8, wherein the material for the liner is one of Ti, TiN, Ta, TaN and Ru, or their combinations.

10. The method according to claim 1, wherein the material of the second dielectric layer is SiN.

11. The method according to claim 1, wherein the material of the contact plug is one of W, Al and TiAl alloy, or their combinations.

12. The method according to claim 1, wherein the material for the first dielectric layer is one of FSG, BPSG, PSG, USG, SiON and a low-K material, or their combinations.

13. The method according to claim 1, wherein after forming the contact plug at step e), the method further comprises: removing the second dielectric layer.

14. A semiconductor structure, which comprises a substrate a gate stack, a first dielectric layer, a second dielectric layer and a contact plug, wherein:
the source/drain regions are embedded into the substrate;
the gate stack is formed on the substrate;
the first dielectric layer covers the source/drain regions, and the second dielectric layer covers the first dielectric layer or covers the first dielectric layer and the gate stack; and
the contact plug is embedded into the first dielectric layer and the second dielectric layer, wherein the cross-sectional area of the contact plug embedded into the second dielectric layer is smaller than the cross-sectional area of the contact plug embedded into the first dielectric layer.

15. The semiconductor structure according to claim 14, further comprising a contact layer which is adjacent to the source/drain regions and is embedded only between the contact plug and the source/drain regions.

16. The semiconductor structure according to claim 14, wherein:
a liner is further formed between the contact plug and the source/drain regions, and between the first dielectric layer and the second dielectric layer.

17. The semiconductor structure according to claim 14, wherein:
the source/drain regions are raised source/drain regions, and the second contact hole extends to such a position inside the source/drain regions that is at the same level as the bottom of the gate stack.

18. The semiconductor structure according to claim 15, wherein an amorphous layer is further conformally formed between the contact layer and the source/drain regions.

19. The semiconductor structure according to claim 16, wherein:
the contact layer is SiNi, SiTi, SiCo or SiCu.

20. The semiconductor structure according to claim 17, wherein:
the material for the liner is one of Ti, TiN, Ta, TaN and Ru, or their combinations.

21. The semiconductor structure according to claim 14, wherein:
the material for the contact plug is one of W, Al and TiAl alloy, or their combinations.

22. The semiconductor structure according to claim 14, wherein:
the material for the first dielectric layer is one of FSG, BPSG, PSG, USG, SiON, and a low-K material, or their combinations.

23. The semiconductor structure according to claim 14, wherein the material for the second dielectric layer is SiN.
